(19) United States
(12) Patent Application Publication
(10) Pub. No.: US 2025/0125781 A1
(43) Pub. Date: Apr. 17, 2025

(54) MULTILAYER FILTER DEVICE

(71) Applicant: TDK CORPORATION, Tokyo (JP)

(72) Inventors: Yuta ASHIDA, Tokyo (JP); Shin Takane, Tokyo (JP); Shuhei Sawaguchi, Tokyo (JP); Tomonori Terui, Tokyo (JP); Keigo Shibuya, Tokyo (JP); Tetsuzo Goto, Tokyo (JP); Masahiro Tatematsu, Tokyo (JP)

(73) Assignee: TDK CORPORATION, Tokyo (JP)

(21) Appl. No.: 18/910,435

(22) Filed: Oct. 9, 2024

(30) Foreign Application Priority Data
Oct. 13, 2023 (JP) 2023-177248

(51) Int. Cl. H03H 7/01

(52) U.S. Cl. CPC H03H 7/0161; H03H 7/0115

(57) ABSTRACT

A filter device includes a stack including a plurality of dielectric layers stacked together, and a resonator configured using a conductor integrated into the stack. Each of the plurality of dielectric layers is formed of a dielectric material, and has a resonance frequency that changes depending on a temperature. In the dielectric material, the resonance frequency changes linearly with respect to a change in the temperature when the temperature is within a first temperature range, and the resonance frequency changes nonlinearly with respect to the change in the temperature when the temperature is within a second temperature range.

### CROSS REFERENCE TO RELATED APPLICATIONS

This application claims the benefit of Japanese Priority Patent Application No. 2023-177248 filed on Oct. 13, 2023, the entire contents of which are incorporated herein by reference.

### BACKGROUND

The technology relates to a multilayer filter device including a stack including a plurality of dielectric layers.

The recent market demands for reduction in size and footprint of the compact mobile communication apparatuses and also requires miniaturization of bandpass filters for use in those communication apparatuses. As a bandpass filter suitable for miniaturization, a bandpass filter using a stack including a plurality of dielectric layers stacked together and a plurality of conductor layers is known. Hereinafter, a bandpass filter using a stack will be referred to as a multilayer bandpass filter.

The characteristics of the multilayer bandpass filter can change depending on the temperature. One of the factors that can change the characteristics of the multilayer bandpass filter is the temperature characteristics of the dielectric layer. U.S. 2022/0294407 A1 discloses a technology of suppressing a change in pass attenuation characteristics of a multilayer filter device due to a temperature, by focusing on a temperature coefficient of a resonance frequency of a dielectric material constituting a dielectric layer.

U.S. 2022/0294407 A1 focuses on a sign and magnitude of an absolute value of the temperature coefficient of the resonance frequency of the dielectric material. However, in U.S. 2022/0294407 A1, the temperature characteristics of the dielectric material other than the sign and the magnitude of the absolute value of the temperature coefficient of the resonance frequency of the dielectric material are not focused on, as means for suppressing the change in the pass attenuation characteristics of the multilayer filter device due to the temperature.

### SUMMARY

A multilayer filter device according to one embodiment of the technology includes a stack including a plurality of dielectric layers stacked together, and a resonator configured using a conductor integrated into the stack. Each of the plurality of dielectric layers is formed of a dielectric material, and has a resonance frequency that changes depending on a temperature. In the dielectric material, the resonance frequency changes linearly with respect to a change in the temperature when the temperature is within a first temperature range, and the resonance frequency changes nonlinearly with respect to the change in the temperature when the temperature is within a second temperature range.

Other and further objects, features and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a circuit diagram showing an example of a circuit configuration of a multilayer filter device according to a first example embodiment of the technology.

FIG. 2 is a perspective view showing an appearance of the multilayer filter device according to the first example embodiment of the technology.

FIG. 3 is an explanatory diagram showing a patterned surface of a first dielectric layer in a stack of the multilayer filter device according to the first example embodiment of the technology.

FIG. 4 is an explanatory diagram showing a patterned surface of a second dielectric layer in the stack of the multilayer filter device according to the first example embodiment of the technology.

FIG. 5 is an explanatory diagram showing a patterned surface of a third dielectric layer in the stack of the multilayer filter device according to the first example embodiment of the technology.

FIG. 6 is an explanatory diagram showing a patterned surface of a fourth dielectric layer in the stack of the multilayer filter device according to the first example embodiment of the technology.

FIG. 7 is an explanatory diagram showing a patterned surface of each of fifth and sixth dielectric layers in the stack of the multilayer filter device according to the first example embodiment of the technology.

FIG. 8 is an explanatory diagram showing a patterned surface of a seventh dielectric layer in the stack of the multilayer filter device according to the first example embodiment of the technology.

FIG. 9 is an explanatory diagram showing a patterned surface of an eighth dielectric layer in the stack of the multilayer filter device according to the first example embodiment of the technology.

FIG. 10 is an explanatory diagram showing a patterned surface of a ninth dielectric layer in the stack of the multilayer filter device according to the first example embodiment of the technology.

FIG. 11 is an explanatory diagram showing a patterned surface of a tenth dielectric layer in the stack of the multilayer filter device according to the first example embodiment of the technology.

FIG. 12 is an explanatory diagram showing a patterned surface of each of eleventh to seventeenth dielectric layers in the stack of the multilayer filter device according to the first example embodiment of the technology.

FIG. 13 is an explanatory diagram showing a patterned surface of an eighteenth dielectric layer in the stack of the multilayer filter device according to the first example embodiment of the technology.

FIG. 14 is an explanatory diagram showing a patterned surface of a nineteenth dielectric layer in the stack of the multilayer filter device according to the first example embodiment of the technology.

FIG. 15 is a perspective view showing an inside of the stack of the multilayer filter device according to the first example embodiment of the technology.

FIG. 16 is a characteristic chart showing temperature characteristics of a resonance frequency of the dielectric layer in the first example embodiment of the technology.

FIG. 17 is a circuit diagram showing an example of a circuit configuration of a multilayer filter device according to a second example embodiment of the technology.

FIG. 18 is a perspective view showing an appearance of the multilayer filter device according to the second example embodiment of the technology.

FIGS. 19A, 19B, and 19C are explanatory diagrams showing respective patterned surfaces of first, second, and third dielectric layers in a stack of the multilayer filter device according to the second example embodiment of the technology.

FIGS. 20A, 20B, and 20C are explanatory diagrams showing respective patterned surfaces of fourth, fifth, and sixth dielectric layers in the stack of the multilayer filter device according to the second example embodiment of the technology.

FIG. 21A is an explanatory diagram showing a patterned surface of a seventh dielectric layer in the stack of the multilayer filter device according to the second example embodiment of the technology.

FIG. 21B is an explanatory diagram showing a patterned surface of each of eighth to fourteenth dielectric layers in the stack of the multilayer filter device according to the second example embodiment of the technology.

FIG. 21C is an explanatory diagram showing a patterned surface of a fifteenth dielectric layer in the stack of the multilayer filter device according to the second example embodiment of the technology.

FIG. 22A is an explanatory diagram showing a patterned surface of a sixteenth dielectric layer in the stack of the multilayer filter device according to the second example embodiment of the technology.

FIG. 22B is an explanatory diagram showing a patterned surface of each of seventeenth to twenty-third dielectric layers in the stack of the multilayer filter device according to the second example embodiment of the technology.

FIG. 22C is an explanatory diagram showing a patterned surface of a twenty-fourth dielectric layer in the stack of the multilayer filter device according to the second example embodiment of the technology.

FIGS. 23A, 23B, and 23C are explanatory diagrams showing respective patterned surfaces of twenty-fifth, twenty-sixth, and twenty-seventh dielectric layers in the stack of the multilayer filter device according to the second example embodiment of the technology.

FIG. 24 is a perspective view showing an inside of the stack of the multilayer filter device according to the second example embodiment of the technology.

FIG. 25 is a characteristic chart showing temperature coefficients of resonance frequencies of dielectric layers of first to third examples.

FIG. 26 is a characteristic chart showing the temperature coefficients of the resonance frequencies of the dielectric layers of third to eighth examples.

FIG. 27 is a characteristic chart showing insertion loss of a multilayer filter device of a ninth example.

FIG. 28 is a characteristic chart showing pass attenuation characteristics of the multilayer filter device of the ninth example.

### DETAILED DESCRIPTION

An object of the technology is to provide a multilayer filter device that can suppress a change in characteristics due to a temperature.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

First, an outline of a configuration of a multilayer filter device (hereinafter, simply referred to as a filter device) 1 according to a first example embodiment of the technology will be briefly described. The filter device 1 according to the example embodiment includes a stack including a plurality of dielectric layers stacked together, and a plurality of resonators configured using a conductor integrated into the stack. Each of the plurality of dielectric layers is formed of a dielectric material, and has a resonance frequency that changes depending on a temperature. The dielectric material will be described in detail later.

The plurality of resonators are configured so that the filter device 1 functions as a filter that filters a signal. Each of the plurality of resonators may be an LC resonator including an inductor and a capacitor, or may be a distributed constant resonator at least part of which is formed of a distributed constant line.

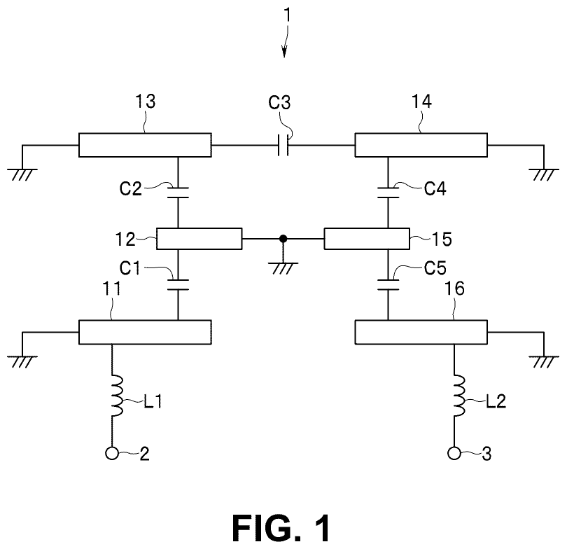

In the example embodiment, each of the plurality of resonators is a distributed constant resonator. Hereinafter, an example of a circuit configuration of the filter device 1 including a plurality of distributed constant resonators will be described. FIG. 1 is a circuit diagram showing the example of the circuit configuration of the filter device 1. The filter device 1 includes a first terminal 2, a second terminal 3, and six resonators 11, 12, 13, 14, 15, and 16. Each of the first terminal 2 and the second terminal 3 is a terminal for input or output of a signal. In other words, when a signal is input to the first terminal 2, a signal is output from the second terminal 3. When a signal is input to the second terminal 3, a signal is output from the first terminal 2.

The six resonators 11, 12, 13, 14, 15, and 16 are provided between the first terminal 2 and the second terminal 3 in a circuit configuration. In addition, the six resonators 11, 12, 13, 14, 15, and 16 are arranged in this order from the first terminal 2 side in the circuit configuration. Note that in the present application, the phrase “in the (a) circuit configuration” is used to refer to a layout in a circuit diagram, not in a physical configuration.

In the resonators 11 to 16, the resonators 11 and 12 are adjacent to each other in the circuit configuration and electromagnetically coupled to each other, the resonators 12 and 13 are adjacent to each other in the circuit configuration and electromagnetically coupled to each other, the resonators 13 and 14 are adjacent to each other in the circuit configuration and electromagnetically coupled to each other, the resonators 14 and 15 are adjacent to each other in the circuit configuration and electromagnetically coupled to each other, and the resonators 15 and 16 are adjacent to each other in the circuit configuration and electromagnetically coupled to each other. In the example embodiment in particular, electromagnetic coupling between each two of the resonators adjacent to each other in the circuit configuration is capacitive.

The resonators 11 to 16 are configured so that two specific resonators not adjacent to each other in the circuit configuration are configured to be electromagnetically coupled to each other. In the example embodiment, a pair of the resonators 12 and 15, a pair of the resonators 11 and 13, and a pair of the resonators 14 and 16 are each configured to be electromagnetically coupled. In the example embodiment in particular, electromagnetic coupling between the resonators 12 and 15, electromagnetic coupling between the resonators 11 and 13, and electromagnetic coupling between the resonators 14 and 16 are each inductive.

In the example embodiment in particular, each of the resonators 11 to 16 is a single-ended short-circuit quarter wavelength resonator that is short-circuited at one end and open at the other end.

The filter device 1 further includes a capacitor C1 for establishing capacitive coupling between the resonators 11 and 12, a capacitor C2 for establishing capacitive coupling between the resonators 12 and 13, a capacitor C3 for establishing capacitive coupling between the resonators 13 and 14, a capacitor C4 for establishing capacitive coupling between the resonators 14 and 15, and a capacitor C5 for establishing capacitive coupling between the resonators 15 and 16.

The filter device 1 further includes an inductor L1 provided between the first terminal 2 and the resonator 11 in the circuit configuration, and an inductor L2 provided between the second terminal 3 and the resonator 16 in the circuit configuration. One end of the inductor L1 is electrically connected to the first terminal 2. The other end of the inductor L1 is electrically connected to the resonator 11. One end of the inductor L2 is electrically connected to the second terminal 3. The other end of the inductor L2 is electrically connected to the resonator 16. Note that in the present application, the phrase “electrically connected” includes a case of being electrically connected through a metal conductor (including an inductor) but does not include a case of being connected through a capacitor.

In the example shown in FIG. 1, the resonators 11 to 16, the capacitors C1 to C5, and the inductors L1 and L2 are configured so that the filter device 1 functions as a bandpass filter that selectively allows a signal in a predetermined frequency band to pass.

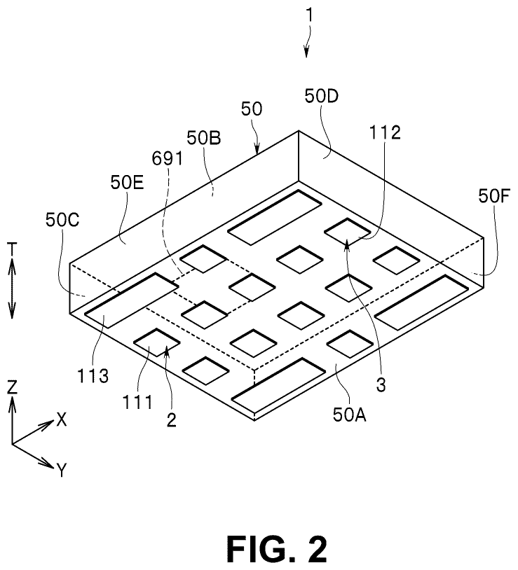

Reference is now made to FIG. 2 to describe other configurations of the filter device 1. FIG. 2 is a perspective view showing an appearance of the filter device 1. The filter device 1 further includes a stack 50 that includes a plurality of dielectric layers stacked together, and a plurality of conductors (a plurality of conductor layers and a plurality of through holes). The first terminal 2, the second terminal 3, the resonators 11 to 16, the capacitors C1 to C5, and the inductors L1 and L2 are integrated into the stack 50.

The stack 50 has a bottom surface 50A and a top surface 50B located at both respective ends in a stacking direction T of the plurality of dielectric layers, and four side surfaces 50C to 50F connecting the bottom surface 50A and the top surface 50B. The side surfaces 50C and 50D face opposite sides of each other and the side surfaces 50E and 50F also face opposite sides of each other. The side surfaces 50C to 50F are perpendicular to the bottom surface 50A and the top surface 50B.

Here, X, Y, and Z directions are defined as shown in FIG. 2. The X, Y, and Z directions are orthogonal to one another. In the example embodiment, a direction parallel to the stacking direction T will be referred to as the Z direction. The opposite directions to the X, Y, and Z directions are defined as −X, −Y, and −Z directions, respectively. The expression “when seen in the stacking direction T” means that a target object is seen from a position away in the Z direction or the −Z direction.

As shown in FIG. 2, the bottom surface 50A is located at the end of the stack 50 in the −Z direction. The top surface 50B is located at the end of the stack 50 in the Z direction. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

The filter device 1 further includes electrodes 111 and 112 provided on the bottom surface 50A of the stack 50. The electrode 111 is arranged near the side surface 50C. The electrode 112 is arranged near the side surface 50D. The electrode 111 corresponds to the first terminal 2, and the electrode 112 corresponds to the second terminal 3. The first and second terminals 2 and 3 are thus provided on the bottom surface 50A of the stack 50.

The filter device 1 further includes a plurality of ground electrodes 113 provided on the bottom surface 50A of the stack 50. In the example embodiment in particular, the plurality of ground electrodes 113 include a plurality of electrodes arranged between the electrodes 111 and 112 and the side surface 50E, a plurality of electrodes arranged between the electrodes 111 and 112 and the side surface 50F, and a plurality of electrodes arranged between the electrode 111 and the electrode 112. Each of the plurality of ground electrodes 113 is connected to the ground.

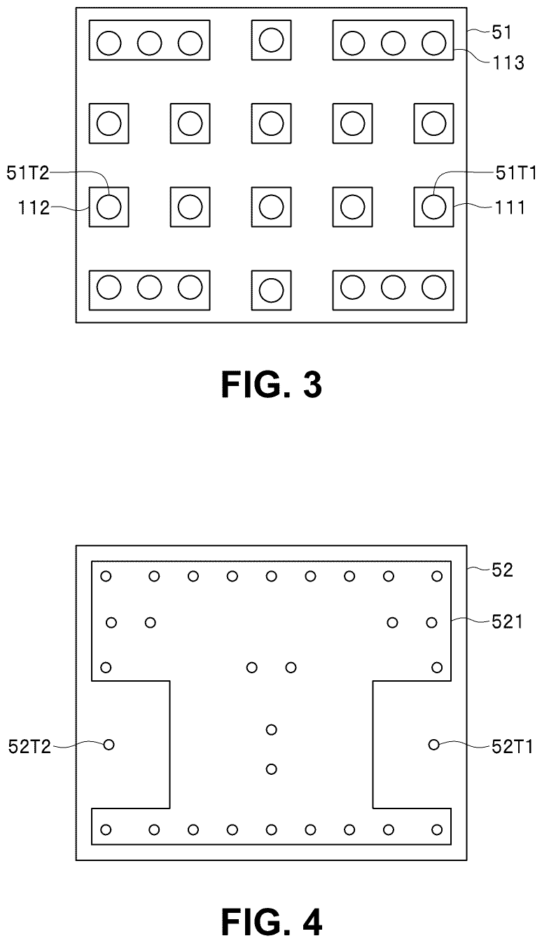

Reference is now made to FIG. 3 to FIG. 14 to describe an example of the plurality of dielectric layers and the plurality of conductors constituting the stack 50. In this example, the stack 50 includes nineteen dielectric layers stacked together. In the following, the nineteen dielectric layers will be referred to as first to nineteenth dielectric layers in the order from bottom to top. The first to nineteenth dielectric layers are denoted by the reference signs 51 to 69, respectively.

In FIG. 3 to FIG. 12, each of a plurality of circles represents a through hole. The dielectric layers 51 to 67 each have a plurality of through holes formed therein. The plurality of through holes are each formed by filling a hole intended for a through hole with a conductive paste. Each of the plurality of through holes is connected to an electrode, a conductor layer, or another through hole. In the following description, for a connection relationship between each of the plurality of through holes and the electrode, the conductor layer, or the other through hole, the connection relationship in a state where the first to nineteenth dielectric layers 51 to 69 are stacked together will be described. In FIG. 3 to FIG. 12, a plurality of specific through holes among the plurality of through holes are denoted by respective reference signs.

FIG. 3 shows a patterned surface of the first dielectric layer 51. The electrodes 111 and 112 and the plurality of ground electrodes 113 are formed on the patterned surface of the dielectric layer 51.

In FIG. 3, through holes denoted by the respective reference signs 51T1 and 51T2 are connected to the electrodes 111 and 112, respectively. Note that, in the following description, the through hole denoted by the reference sign 51T1 will be referred to simply as a through hole 51T1. Each through hole denoted by a reference sign other than the through hole 51T1 will be referred to similarly as the through hole 51T1.

FIG. 4 shows a patterned surface of the second dielectric layer 52. A conductor layer 521 is formed on the patterned surface of the dielectric layer 52. The through holes 51T1 and 51T2 are connected to through holes 52T1 and 52T2 shown in FIG. 4, respectively.

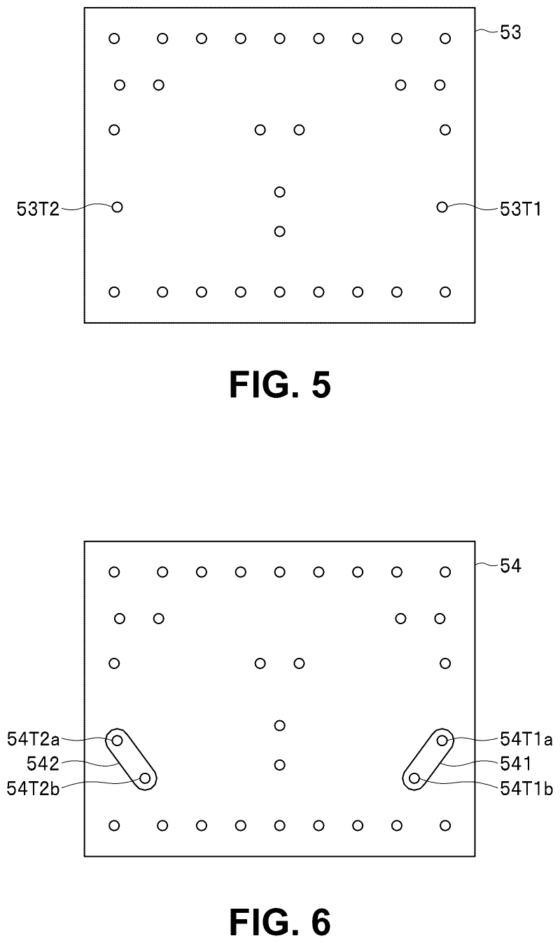

FIG. 5 shows a patterned surface of the third dielectric layer 53. The through holes 52T1 and 52T2 are connected to through holes 53T1 and 53T2 shown in FIG. 5, respectively.

FIG. 6 shows a patterned surface of the fourth dielectric layer 54. Inductor conductor layers 541 and 542 are formed on the patterned surface of the dielectric layer 54. The through hole 53T1 and through holes 54T1a and 54T1b shown in FIG. 6 are connected to the conductor layer 541. The through hole 53T2 and through holes 54T2a and 54T2b shown in FIG. 6 are connected to the conductor layer 542.

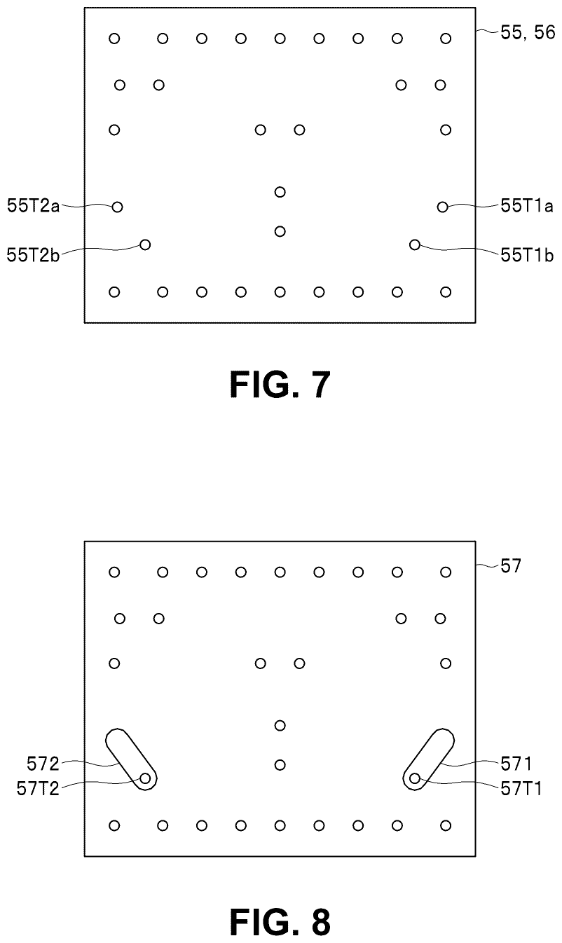

FIG. 7 shows a patterned surface of each of the fifth and sixth dielectric layers 55 and 56. The through holes 54T1a, 54T1b, 54T2a, and 54T2b are connected to through holes 55T1a, 55T1b, 55T2a, and 55T2b formed in the dielectric layer 55, respectively. In the dielectric layers 55 and 56, every vertically adjacent through holes denoted by the same reference signs are connected to each other.

FIG. 8 shows a patterned surface of the seventh dielectric layer 57. Inductor conductor layers 571 and 572 are formed on the patterned surface of the dielectric layer 57. The through holes 55T1a and 55T1b formed in the dielectric layer 56 and a through hole 57T1 shown in FIG. 8 are connected to the conductor layer 571. The through holes 55T2a and 55T2b formed in the dielectric layer 56 and a through hole 57T2 shown in FIG. 8 are connected to the conductor layer 572.

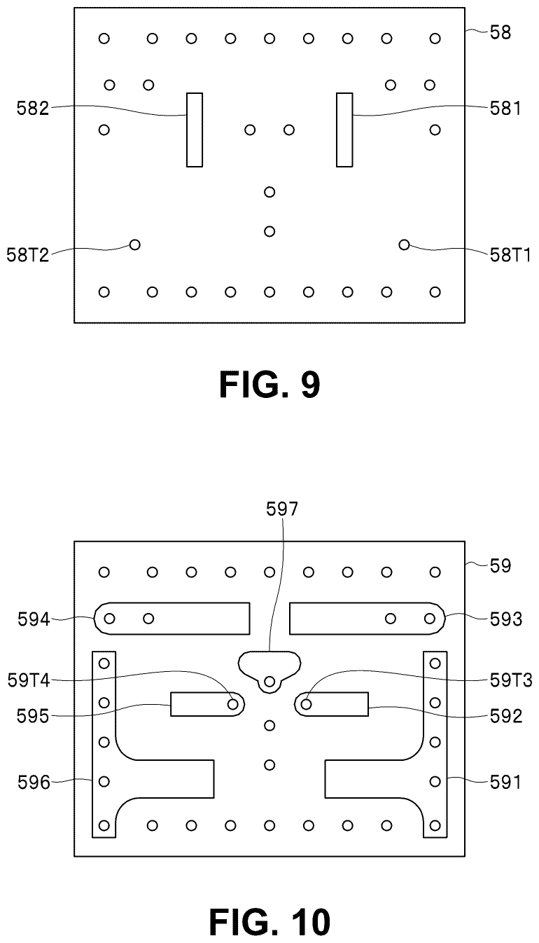

FIG. 9 shows a patterned surface of the eighth dielectric layer 58. Conductor layers 581 and 582 are formed on the patterned surface of the dielectric layer 58. The through holes 57T1 and 57T2 are connected to through holes 58T1 and 58T2 shown in FIG. 9, respectively.

FIG. 10 shows a patterned surface of the ninth dielectric layer 59. Resonator conductor layers 591, 592, 593, 594, 595, and 596 and a conductor layer 597 are formed on the patterned surface of the dielectric layer 59. Each of the conductor layers 591 and 596 includes a portion extending in one direction. Each of the conductor layers 592 to 595 has a shape that is long in one direction.

The through holes 58T1 and 58T2 are connected to the conductor layers 591 and 596, respectively. Through holes 59T3 and 59T4 shown in FIG. 10 are connected to the conductor layers 592 and 595, respectively.

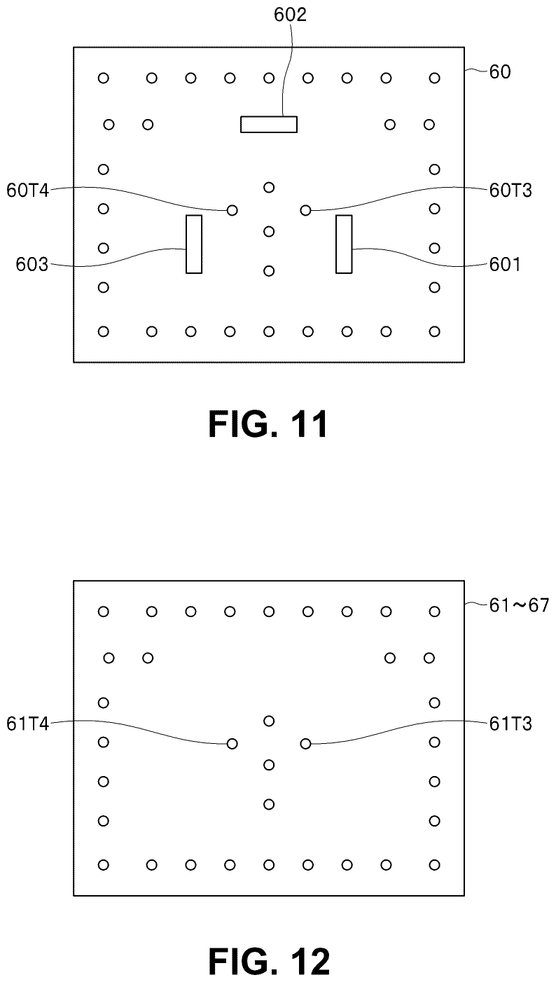

FIG. 11 shows a patterned surface of the tenth dielectric layer 60. Conductor layers 601, 602, and 603 are formed on the patterned surface of the dielectric layer 60. The through holes 59T3 and 59T4 are connected to through holes 60T3 and 60T4 shown in FIG. 11, respectively.

FIG. 12 shows a patterned surface of each of the eleventh to seventeenth dielectric layers 61 to 67. The through holes 60T3 and 60T4 are connected to through holes 61T3 and 61T4 formed in the dielectric layer 61, respectively. In the dielectric layers 61 to 67, every vertically adjacent through holes denoted by the same reference signs are connected to each other.

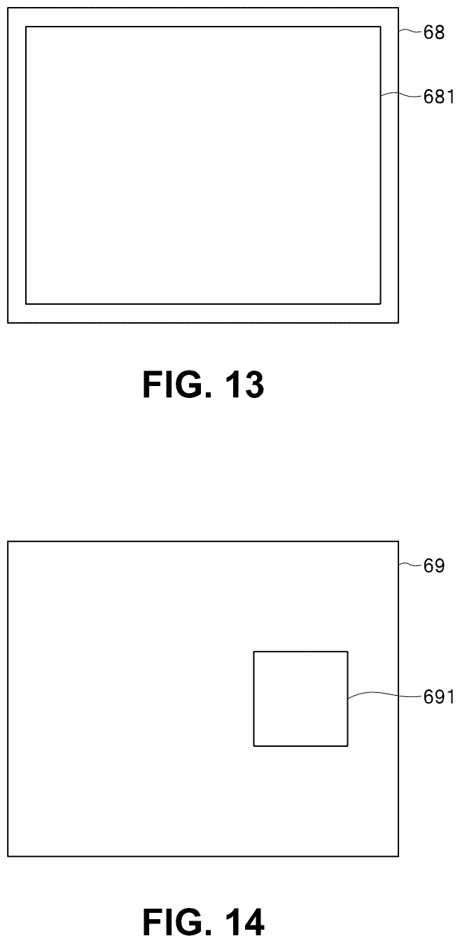

FIG. 13 shows a patterned surface of the eighteenth dielectric layer 68. A conductor layer 681 is formed on the patterned surface of the dielectric layer 68. The through holes 61T3 and 61T4 formed in the dielectric layer 67 are connected to the conductor layer 681.

FIG. 14 shows a patterned surface of the nineteenth dielectric layer 69. A mark 691 is formed on the patterned surface of the dielectric layer 69.

The stack 50 shown in FIG. 2 is formed by stacking the first to nineteenth dielectric layers 51 to 69 such that the patterned surface of the first dielectric layer 51 serves as the bottom surface 50A of the stack 50 and a surface opposite to the patterned surface of the nineteenth dielectric layer 69 serves as the top surface 50B of the stack 50.

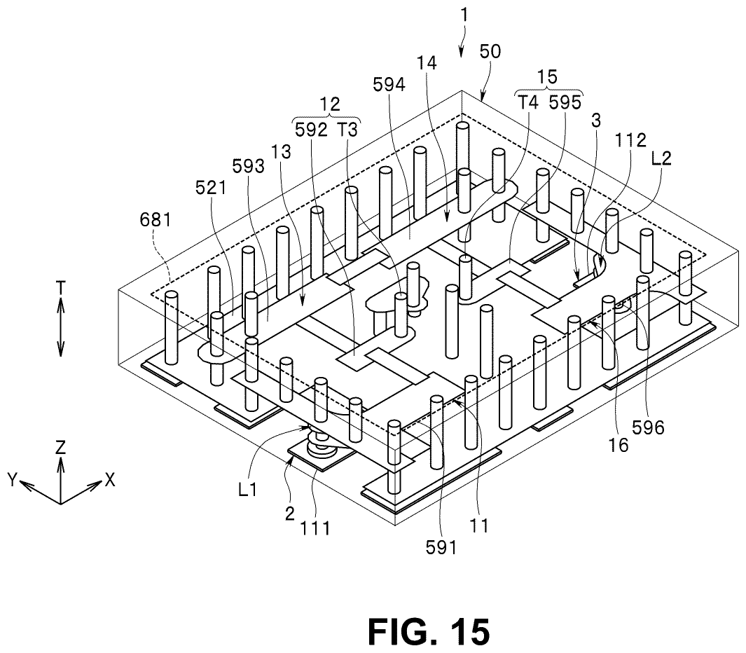

FIG. 15 shows an inside of the stack 50 formed by stacking the first to nineteenth dielectric layers 51 to 69. As shown in FIG. 15, the plurality of conductor layers and the plurality of through holes shown in FIG. 3 to FIG. 13 are stacked together inside the stack 50. Note that, in FIG. 15, the mark 691 is omitted.

Correspondences between the components of the filter device 1 shown in FIG. 1 and the internal components of the stack 50 shown in FIG. 2 to FIG. 14 will be described below. The resonator 11 is composed of the resonator conductor layer 591. The resonator 13 is composed of the resonator conductor layer 593. The resonator 14 is composed of the resonator conductor layer 594. The resonator 16 is composed of the resonator conductor layer 596.

The resonator 12 is composed of the resonator conductor layer 592 and the through holes 59T3, 60T3, and 61T3. In FIG. 15, the reference sign T3 denotes a structure formed by connecting the through holes 59T3, 60T3, and 61T3 in series. A structure formed by connecting two or more through holes in series will also be referred to as a through hole below. The resonator 12 can be said to be composed of the conductor layer 592 and the through hole T3. One end of the through hole T3 is connected to the conductor layer 592. The other end of the through hole T3 is connected to the conductor layer 681.

The resonator 15 is composed of the resonator conductor layer 595 and the through hole T4. The through hole T4 is formed by connecting the through holes 59T4, 60T4, and 61T4 in series. One end of the through hole T4 is connected to the conductor layer 595. The other end of the through hole T4 is connected to the conductor layer 681.

The capacitor C1 is composed of the conductor layers 591, 592, and 601 and the dielectric layer 59 interposed between those conductor layers. The capacitor C2 is composed of the conductor layers 581, 592, and 593 and the dielectric layer 58 interposed between those conductor layers. The capacitor C3 is composed of the conductor layers 593, 594, and 602 and the dielectric layer 59 interposed between those conductor layers. The capacitor C4 is composed of the conductor layers 582, 594, and 595 and the dielectric layer 58 interposed between those conductor layers. The capacitor C5 is composed of the conductor layers 595, 596, and 603 and the dielectric layer 59 interposed between those conductor layers.

The inductor L1 is composed of the conductor layers 541 and 571 and the through holes 54T1a, 54T1b, 55T1a, and 55T1b. The conductor layer 541 is connected to the electrode 111 corresponding to the first terminal 2 through the through holes 51T1, 52T1, and 53T1. The conductor layer 571 is connected to the resonator conductor layer 591 constituting the resonator 11 through the through holes 57T1 and the 58T1.

The inductor L2 is composed of the conductor layers 542 and 572 and the through holes 54T2a, 54T2b, 55T2a, and 55T2b. The conductor layer 542 is connected to the electrode 112 corresponding to the second terminal 3 through the through holes 51T2, 52T2, and 53T2. The conductor layer 572 is connected to the resonator conductor layer 596 constituting the resonator 16 through the through holes 57T2 and 58T2.

Next, a method of manufacturing the filter device 1 according to the example embodiment will be briefly described. In the example embodiment in particular, each of the dielectric layers 51 to 69 is a ceramic sintered body containing dielectric ceramics, which are dielectric materials. The stack 50 is fabricated, for example, by a low-temperature co-firing method. In this case, first, a plurality of green sheets are fabricated, which will later become the dielectric layers 51 to 69 respectively. Each of the green sheets is formed from a mixture containing raw material powder including the dielectric ceramics and glass, an additive, an organic binder, an organic solvent, and the like. Next, on each of the green sheets, a plurality of unfired conductor layers, which will later become the plurality of conductor layers, and a plurality of unfired through holes, which will later become the plurality of through holes, are formed. Next, the plurality of green sheets are stacked to fabricate a green sheet stack. Next, the green sheet stack is cut to fabricate an unfired stack. Next, the dielectric ceramics and the conductors in the unfired stack are fired in a low-temperature co-firing process to complete the stack 50.

As described above, each of the dielectric layers 51 to 69 is formed by the dielectric material. The dielectric layer (ceramic sintered body) formed of the dielectric material has characteristics that change depending on the temperature. Here, a resonance frequency of the dielectric layer is focused on. As an example of an indicator that shows a temperature dependence of the resonance frequency of the dielectric layer includes a temperature coefficient TCF of the resonance frequency. The temperature coefficient TCF of the resonance frequency (unit: ppm/K) is expressed by the following formula (1), as defined in JIS standard R1627 (test method of dielectric properties of fine ceramics for microwave). Note that f_{ref} represents the resonance frequency at a reference temperature t_{ref}, and f_{T} represents the resonance frequency at a predetermined temperature t.

TCF=[(f_{T}−f_{ref})/{f_{ref}(t−t_{ref})}]×10⁶ (1)

The technician of the present application found that, by focusing on an aspect of a change in the the resonance frequency f_{T} when the temperature t is changed, it is possible to suppress a change in the characteristics of the filter device 1 due to the temperature. Here, a range of the temperature t that includes at least one continuous range is referred to as a first temperature range, and a range of the temperature t that includes a continuous range that differs from the first temperature range is referred to as a second temperature range. In the dielectric material in the example embodiment, the aspect of the change in the resonance frequency f_{T} differs between within the first temperature range and within the second temperature range.

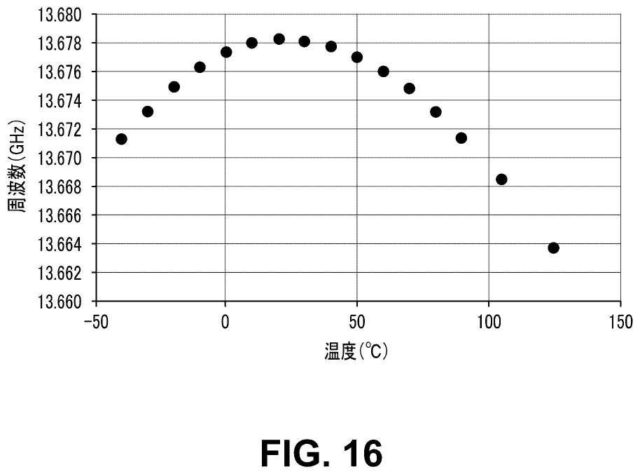

FIG. 16 is a characteristic chart showing temperature characteristics of the resonance frequency f_{T} of the dielectric layer in the example embodiment. In FIG. 16, the horizontal axis represents the temperature t, and the vertical axis represents the resonance frequency f_{T}. In the dielectric material in the example embodiment, the resonance frequency f_{T} changes linearly with respect to a change in the temperature t when the temperature t is within the first temperature range, and the resonance frequency f_{T} changes nonlinearly with respect to the change in the temperature t when the temperature t is within the second temperature range. Note that “change linearly” means that, in the characteristic chart representing the relationship between the resonance frequency f_{T} and the temperature t, the resonance frequency f_{T} changes linearly or substantially linearly to an extent that the relationship between the resonance frequency f_{T} and the temperature t can be approximated by a linear function. When the resonance frequency f_{T} of the dielectric layer changes linearly, the resonance frequency f_{T} may increase monotonically with respect to the change in the temperature t or may increase while repeating slight increases and decreases, or may decrease monotonically with respect to the change in the temperature t or may decrease while repeating slight increases and decreases.

Note that “change nonlinearly” means that in the above characteristic chart, the resonance frequency f_{T} does not change linearly or substantially linearly, for example, changes in a curve. In the example embodiment, the resonance frequency f_{T} can be said to “change nonlinearly” when the resonance frequency f_{T} changes in the curve to an extent that the relationship between the resonance frequency f_{T} and the temperature t can be approximated by a quadratic function.

In the example shown in FIG. 16, the second temperature range is a temperature range including 20° C. The second temperature range may be, for example, 0° C. to 40° C. Within the second temperature range, the resonance frequency f_{T} changes in the curve. When the resonance frequency f_{T} within the second temperature range is approximated by a quadratic function, the slope of the quadratic function may be 0 at the temperature of 20° C. or around 20° C.

Here, when the resonance frequency f_{T} within the second temperature range is approximated by a quadratic function, the temperature t at which the slope of the quadratic function is 0 is referred to as a specific temperature. In the example shown in FIG. 16, an aspect of the change in the resonance frequency f_{T} with respect to the change in the temperature t when the temperature t decreases from the specific temperature and an aspect of the change in the resonance frequency f_{T} with respect to the change in the temperature t when the temperature t increases from the specific temperature are the same. Specifically, in both of the cases where the temperature t decreases from the specific temperature and where the temperature t increases from the specific temperature, the resonance frequency f_{T} decreases. When the temperature t is lower than the specific temperature, the temperature coefficient TCF of the resonance frequency is a positive value, and when the temperature t is higher than the specific temperature, the temperature coefficient TCF of the resonance frequency is a negative value.

In the example shown in FIG. 16, the first temperature range includes a first sub-range lower than the second temperature range and a second sub-range higher than the second temperature range. The first sub-range may be −40° C. to 0° C., for example. The second sub-range may be 40° C. to 125° C., for example. In other words, the second sub-range may be wider than the first sub-range. In both of the first sub-range and the second sub-range, the resonance frequency f_{T} changes substantially linearly.

In the first sub-range, the resonance frequency f_{T} increases monotonically as the temperature t increases. In other words, in the first sub-range, the temperature coefficient TCF of the resonance frequency is a positive value. In the second sub-range, the resonance frequency f_{T} decreases monotonically as the temperature t increases. In other words, in the second sub-range, the temperature coefficient TCF of the resonance frequency is a negative value. Note that the temperature of an upper limit of the second sub-range is not limited to the above example, and may be 85° C., may be 105° C., or may be 150° C.

A difference between a maximum value and a minimum value of the resonance frequency f_{T} in the second temperature range may be smaller than a difference between a maximum value and a minimum value of the resonance frequency f_{T} in the first temperature range. In the example shown in FIG. 16, when the second temperature range is 0° C. to 40° C., the first sub-range of the first temperature range is −40° C. to 0° C., and the second sub-range of the first temperature range is 40° C. to 125° C., the above requirement regarding the maximum values and the minimum values of the resonance frequency f_{T} is met.

It is known that the temperature characteristics of the resonance frequency f_{T} of the ceramic sintered body forming the dielectric layer can be adjusted by changing a mixing rate of the dielectric material. As the dielectric material, various ceramic materials, various glass-ceramic materials used in low-temperature co-fired ceramics (LTCC), and mixtures of these materials can be used, as long as the above requirement for the resonance frequency f_{T} is met. FIG. 16 shows the temperature characteristics of the resonance frequency f_{T} of the ceramic sintered body formed using a dielectric material in which aluminum oxide, silicon oxide, a titanate compound, or the like are mixed.

Next, operation and effects of the filter device 1 according to the example embodiment will be described. As described above, in the dielectric material in the example embodiment, the resonance frequency f_{T} changes linearly with respect to the change in the temperature t when the temperature t is within the first temperature range, and the resonance frequency f_{T} changes nonlinearly with respect to the change in the temperature t when the temperature t is within the second temperature range. As shown in FIG. 16, when comparison is made within the same width of the temperature range, an amount of the change in the resonance frequency f_{T} when the resonance frequency f_{T} changes nonlinearly is smaller than that when the resonance frequency f_{T} changes linearly. Therefore, according to the example embodiment, compared to the case where the resonance frequency f_{T} changes linearly with respect to the change in the temperature t, the amount of the change in the resonance frequency f_{T} with the change in the temperature t can be reduced over the entire specification temperature range of the filter device 1. As a result, according to the example embodiment, the change in the characteristics of the filter device 1 due to the temperature can be suppressed. An example of the characteristics of the filter device 1 will be described later.

In the example embodiment, when the resonance frequency f_{T} within the second temperature range is approximated with a quadratic function, the slope of the quadratic function becomes 0 at the specific temperature. In other words, in the example embodiment, a temperature range in which the resonance frequency f_{T} increases monotonically as the temperature t increases and a temperature range in which the resonance frequency f_{T} decreases monotonically as the temperature t increases exist. In other words, in the example embodiment, a temperature range in which the temperature coefficient TCF of the resonance frequency is a positive value and a temperature range in which the temperature coefficient TCF of the resonance frequency is a negative value exist. Therefore, according to the example embodiment, compared to the case where the resonance frequency f_{T} increases monotonically or decreases monotonically as the temperature t increases, the amount of the change in the resonance frequency f_{T} with the change in the temperature t can be reduced over the entire specification temperature range of the filter device 1, and the temperature coefficient TCF of the resonance frequence over the entire specification temperature range of the filter device 1 can become smaller.

Incidentally, for the filter device 1, in the course of shipping inspections or the like, a pass attenuation or the like of the filter device 1 is inspected at the a lower limit temperature of the first sub-range and an upper limit temperature of the second sub-range. In the example embodiment, within the first sub-range of the first temperature range, the resonance frequency f_{T} increases monotonically as the temperature t increases, and within the second sub-range of the first temperature range, the resonance frequency f_{T} decreases monotonically as the temperature t increases. If the second sub-range is wider than the first sub-range, the amount of the change in the resonance frequency f_{T} in the second sub-range can be made larger than the amount of the change in the resonance frequency f_{T} in the first sub-range. If the minimum value of the resonance frequency f_{T} in the second sub-range is smaller than the minimum value of the resonance frequency f_{T} in the first sub-range, it is possible to omit the characteristic inspection at the lower limit temperature of the first sub-range.

### Second Example Embodiment

Next, a filter device 101 according to a second example embodiment of the technology will be described. The filter device 101 according to the example embodiment includes a stack including a plurality of dielectric layers stacked together and a plurality of resonators configured using a conductor integrated into the stack. Each of the plurality of dielectric layers may be formed of the same material as that of the dielectric layers 51 to 69 in the first example embodiment.

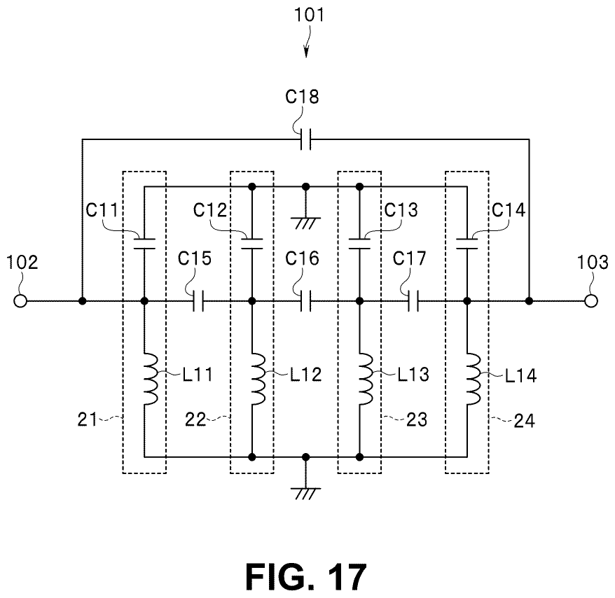

In the example embodiment, each of the plurality of resonators is an LC resonator including an inductor and a capacitor. Hereinafter, an example of a circuit configuration of the filter device 101 including a plurality of LC resonators will be described. FIG. 17 is a circuit diagram showing the example of the circuit configuration of the filter device 101 according to the example embodiment. The filter device 101 includes a first terminal 102, a second terminal 103, and four resonators 21, 22, 23, and 24. Each of the first and second terminals 102 and 103 is a terminal for input or output of a signal.

The four resonators 21, 22, 23, and 24 are provided between the first terminal 102 and the second terminal 103 in the circuit configuration. In addition, the four resonators 21, 22, 23, and 24 are arranged in this order from the first terminal 102 side in the circuit configuration.

The resonator 21 includes an inductor L11 and a capacitor C11. The resonator 22 includes an inductor L12 and a capacitor C12. The resonator 23 includes an inductor L13 and a capacitor C13. The resonator 24 includes an inductor L14 and a capacitor C14.

In the example embodiment in particular, in each of the resonators 21 to 24, the inductor and the capacitor are connected in series. One end of the capacitor C11 is connected to one end of the inductor L11. One end of the capacitor C12 is connected to one end of the inductor L12. One end of the capacitor C13 is connected to one end of the inductor L13. One end of the capacitor C14 is connected to one end of the inductor L14. The other end of each of the inductors L11 to L14 and the capacitors C11 to C14 is connected to the ground.

The one end of each of the inductor L11 and the capacitor C11 is connected to the first terminal 102. The one end of each of the inductor L14 and the capacitor C14 is connected to the second terminal 103.

The filter device 101 further includes capacitors C15, C16, C17, and C18. One end of the capacitor C15 is connected to the one end of each of the inductor L11 and the capacitor C11. The other end of the capacitor C15 and one end of the capacitor C16 are connected to the one end of each of the inductor L12 and the capacitor C12. The other end of the capacitor C16 and one end of the capacitor C17 are connected to the one end of each of the inductor L13 and the capacitor C13. The other end of the capacitor C17 is connected to the one end of each of the inductor L14 and the capacitor C14. One end of the capacitor C18 is connected to the one end of the capacitor C15. The other end of the capacitor C18 is connected to the other end of the capacitor C17.

In the example embodiment, the resonators 21 to 24, the capacitors C11 to C18, and the inductors L11 to L14 are configured so that the filter device 101 functions as a bandpass filter that allows a signal in a predetermined frequency band to pass selectively.

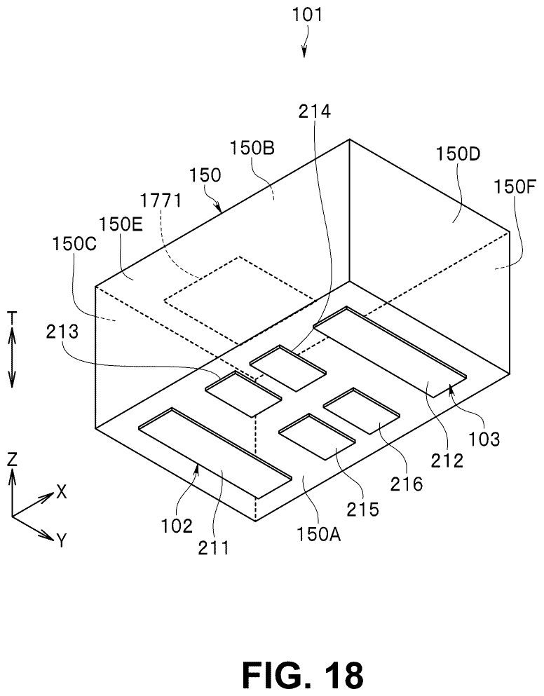

Next, other configurations of the filter device 101 will be described with reference to FIG. 18. FIG. 18 is a perspective view showing an appearance of the filter device 101.

The filter device 101 further includes a stack 150 that includes a plurality of dielectric layers stacked together, and a plurality of conductors (a plurality of conductor layers and a plurality of through holes). The first terminal 102, the second terminal 103, the resonators 21 to 24 (the inductors L11 to L14 and the capacitors C11 to C14), and the capacitors C15 to C18 are integrated into the stack 150.

The stack 150 has a bottom surface 150A and a top surface 150B located at both respective ends in the stacking direction T of the plurality of dielectric layers, and four side surfaces 150C to 150F connecting the bottom surface 150A and the top surface 150B. The side surfaces 150C and 150D face opposite sides of each other and the side surfaces 150E and 150F also face opposite sides of each other. The side surfaces 150C to 150F are perpendicular to the bottom surface 150A and the top surface 150B.

FIG. 18 shows the X, Y, Z directions as in FIG. 2 in the first example embodiment. As shown in FIG. 18, the bottom surface 150A is located at the end of the stack 150 in the −Z direction. The top surface 150B is located at the end of the stack 150 in the Z direction. The side surface 150C is located at the end of the stack 150 in the −X direction. The side surface 150D is located at the end of the stack 150 in the X direction. The side surface 150E is located at the end of the stack 150 in the −Y direction. The side surface 150F is located at the end of the stack 150 in the Y direction.

The filter device 101 further includes electrodes 211 and 212 provided on the bottom surface 150A of the stack 150. The electrode 211 is extended in a direction parallel to the Y direction at a position closer to the side surface 150C than the side surface 150D. The electrode 212 is extended in a direction parallel to the Y direction at a position closer to the side surface 150D than the side surface 150C. The electrode 211 corresponds to the first terminal 102, and the electrode 212 corresponds to the second terminal 103. The first and second terminals 102 and 103 are thus provided on the bottom surface 150A of the stack 150.

The filter device 101 further includes electrodes 213, 214, 215, and 216 provided on the bottom surface 150A of the stack 150. The electrodes 213, 214, 215, and 216 are arranged between the electrode 211 and the electrode 212. The electrodes 213 and 214 are arranged in this order in the X direction at a position closer to the side surface 150E than the side surface 150F. The electrodes 215 and 216 are arranged in this order in the X direction at a position closer to the side surface 150F than the side surface 150E. Each of the electrodes 213, 214, 215, and 216 is connected to the ground.

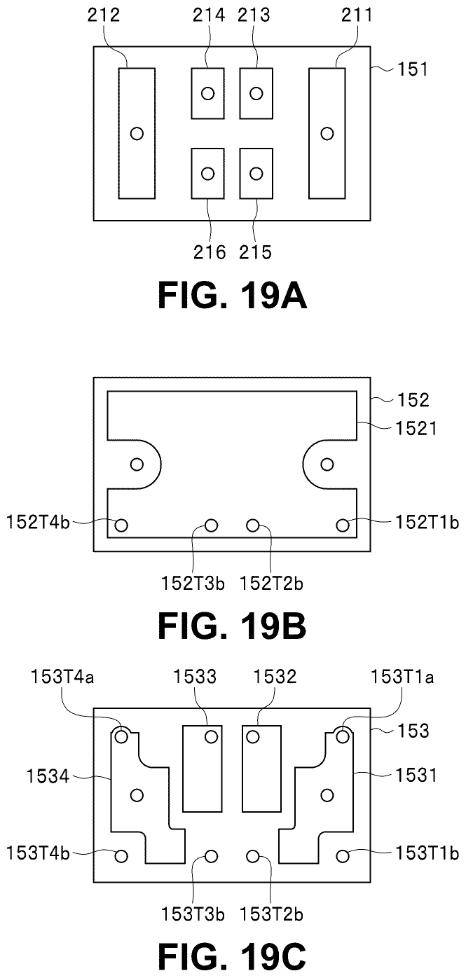

Reference is now made to FIG. 19A to FIG. 23C to describe an example of the plurality of dielectric layers and the plurality of conductors constituting the stack 150. In this example, the stack 150 includes twenty-seven dielectric layers stacked together. In the following, the twenty-seven dielectric layers will be referred to as the first to twenty-seventh dielectric layers in the order from bottom to top. The first to twenty-seventh dielectric layers are denoted by the reference signs 151 to 177, respectively.

In FIG. 19A to FIG. 22C, each of a plurality of circles represents a through hole. The dielectric layers 151 to 174 each have a plurality of through holes formed therein. In the following description, for a connection relationship between each of the plurality of through holes and the electrode, the conductor layer, and the other through holes, the connection relationship in a state where the first to twenty-seventh dielectric layers 151 to 177 are stacked together will be described. In FIG. 19A to FIG. 22C, a plurality of specific through holes among the plurality of through holes are denoted by respective reference signs.

FIG. 19A shows a patterned surface of the first dielectric layer 151. The electrodes 211 to 216 are formed on the patterned surface of the dielectric layer 151.

FIG. 19B shows a patterned surface of the second dielectric layer 152. A conductor layer 1521 is formed on the patterned surface of the dielectric layer 152. Through holes 152T1b, 152T2b, 152T3b, and 152T4b shown in FIG. 19B are connected to the conductor layer 1521.

FIG. 19C shows a patterned surface of the third dielectric layer 153. Conductor layers 1531, 1532, 1533, and 1534 are formed on the patterned surface of the dielectric layer 153. Through holes 153T1a and 153T4a shown in FIG. 19C are connected to the conductor layers 1531 and 1534, respectively. The through holes 152T1b, 152T2b, 152T3b, and 152T4b are connected to through holes 153T1b, 153T2b, 153T3b, and 153T4b shown in FIG. 19C, respectively.

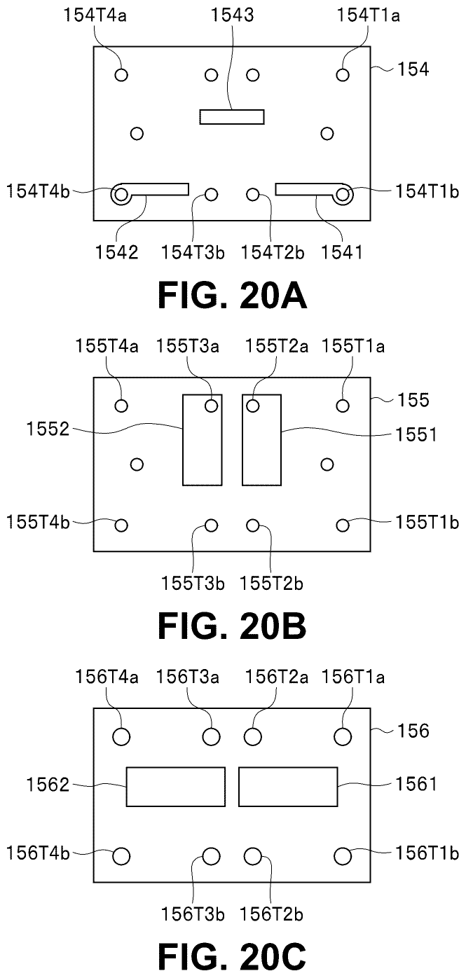

FIG. 20A shows a patterned surface of the fourth dielectric layer 154. Conductor layers 1541, 1542, and 1543 are formed on the patterned surface of the dielectric layer 154. The through holes 153T1a, 153T2b, 153T3b, and 153T4a are connected to through holes 154T1a, 154T2b, 154T3b, and 154T4a shown in FIG. 20A, respectively. The through hole 153T1b and a through hole 154T1b shown in FIG. 20A are connected to the conductor layer 1541. The through hole 153T4b and a through hole 154T4b shown in FIG. 20A are connected to the conductor layer 1542.

FIG. 20B shows a patterned surface of the fifth dielectric layer 155. Conductor layers 1551 and 1552 are formed on the patterned surface of the dielectric layer 155. The through holes 154T1a, 154T1b, 154T2b, 154T3b, 154T4a, and 154T4b are connected to through holes 155T1a, 155T1b, 155T2b, 155T3b, 155T4a, and 155T4b shown in FIG. 20B, respectively. Through holes 155T2a and 155T3a shown in FIG. 20B are connected to the conductor layers 1551 and 1552, respectively.

FIG. 20C shows a patterned surface of the sixth dielectric layer 156. Conductor layers 1561 and 1562 are formed on the patterned surface of the dielectric layer 156. The through holes 155T1a, 155T1b, 155T2a, 155T2b, 155T3a, 155T3b, 155T4a, and 155T4b are connected to through holes 156T1a, 156T1b, 156T2a, 156T2b, 156T3a, 156T3b, 156T4a, and 156T4b shown in FIG. 20C, respectively.

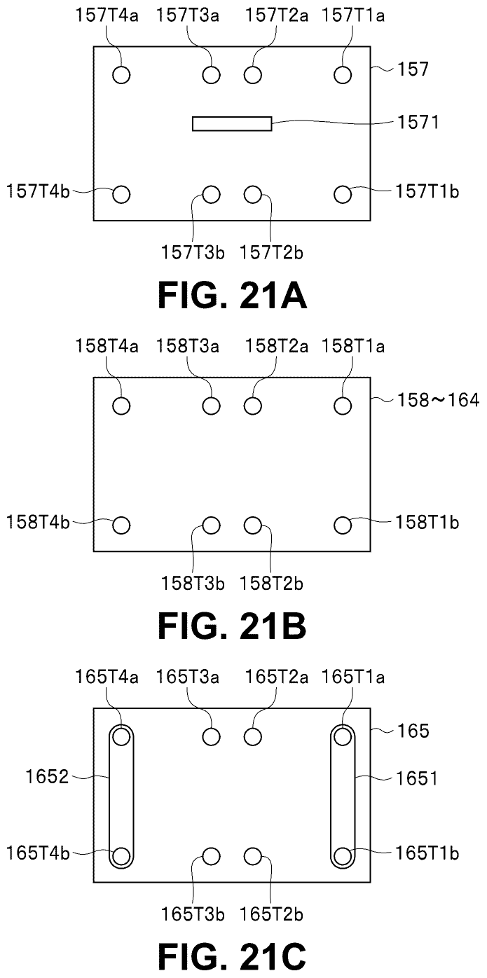

FIG. 21A shows a patterned surface of the seventh dielectric layer 157. A conductor layer 1571 is formed on the patterned surface of the dielectric layer 157. The through holes 156T1a, 156T1b, 156T2a, 156T2b, 156T3a, 156T3b, 156T4a, and 156T4b are connected to through holes 157T1a, 157T1b, 157T2a, 157T2b, 157T3a, 157T3b, 157T4a, and 157T4b shown in FIG. 21A, respectively.

FIG. 21B shows a patterned surface of each of the eighth to fourteenth dielectric layers 158 to 164. The through holes 157T1a, 157T1b, 157T2a, 157T2b, 157T3a, 157T3b, 157T4a, and 157T4b are connected to through holes 158T1a, 158T1b, 158T2a, 158T2b, 158T3a, 158T3b, 158T4a, and 158T4b formed in the dielectric layer 158, respectively. In the dielectric layers 158 to 164, every vertically adjacent through holes denoted by the same reference signs are connected to each other.

FIG. 21C shows a patterned surface of the fifteenth dielectric layer 165. Inductor conductor layers 1651 and 1652 are formed on the patterned surface of the dielectric layer 165. The conductor layer 1651 has a first end and a second end located at both respective ends in a longitudinal direction of the conductor layer 1651. The conductor layer 1652 has a first end and a second end located at both respective ends in a longitudinal direction of the conductor layer 1652. The through hole 158T1a formed in the dielectric layer 164 and a through hole 165T1a shown in FIG. 21C are connected to a portion near the first end of the conductor layer 1651. The through hole 158T1b formed in the dielectric layer 164 and a through hole 165T1b shown in FIG. 21C are connected to a portion near the second end of the conductor layer 1651. The through hole 158T4a formed in the dielectric layer 164 and a through hole 165T4a shown in FIG. 21C are connected to a portion near the first end of the conductor layer 1652. The through hole 158T4b formed in the dielectric layer 164 and a through hole 165T4b shown in FIG. 21C are connected to a portion near the second end of the conductor layer 1652.

The through holes 158T2a, 158T2b, 158T3a, and 158T3b formed in the dielectric layer 164 are connected to through holes 165T2a, 165T2b, 165T3a, and 165T3b shown in FIG. 21C, respectively.

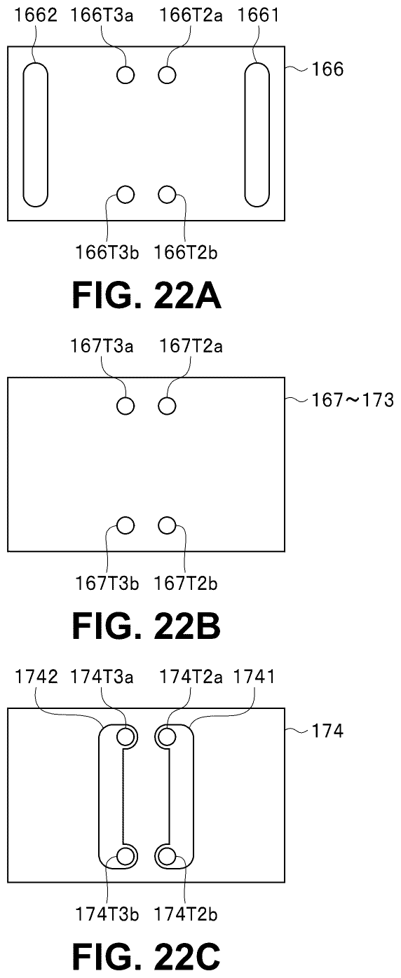

FIG. 22A shows a patterned surface of the sixteenth dielectric layer 166. Inductor conductor layers 1661 and 1662 are formed on the patterned surface of the dielectric layer 166. The conductor layer 1661 has a first end and a second end located at both respective ends in a longitudinal direction of the conductor layer 1661. The conductor layer 1662 has a first end and a second end located at both respective ends in a longitudinal direction of the conductor layer 1662. The through hole 165T1a is connected to a portion near the first end of the conductor layer 1661. The through hole 165T1b is connected to a portion near the second end of the conductor layer 1661. The through hole 165T4a is connected to a portion near the first end of the conductor layer 1662. The through hole 165T4b is connected to a portion near the second end of the conductor layer 1662.

The through holes 165T2a, 165T2b, 165T3a, and 165T3b are connected to through holes 166T2a, 166T2b, 166T3a, and 166T3b shown in FIG. 22A, respectively.

FIG. 22B shows a patterned surface of each of the seventeenth to twenty-third dielectric layers 167 to 173. The through holes 166T2a, 166T2b, 166T3a, and 166T3b are connected to through holes 167T2a, 167T2b, 167T3a, and 167T3b formed in the dielectric layer 167, respectively. In the dielectric layers 167 to 173, every vertically adjacent through holes denoted by the same reference signs are connected to each other.

FIG. 22C shows a patterned surface of the twenty-fourth dielectric layer 174. Inductor conductor layers 1741 and 1742 are formed on the patterned surface of the dielectric layer 174. The conductor layer 1741 has a first end and a second end located at both respective ends in a longitudinal direction of the conductor layer 1741. The conductor layer 1742 has a first end and a second end located at both respective ends in a longitudinal direction of the conductor layer 1742. The through hole 167T2a formed in the dielectric layer 173 and a through hole 174T2a shown in FIG. 22C are connected to a portion near the first end of the conductor layer 1741. The through hole 167T2b formed in the dielectric layer 173 and a through hole 174T2b shown in FIG. 22C are connected to a portion near the second end of the conductor layer 1741. The through hole 167T3a formed in the dielectric layer 173 and a through hole 174T3a shown in FIG. 22C are connected to a portion near the first end of the conductor layer 1742. The through hole 167T3b formed in the dielectric layer 173 and a through hole 174T3b shown in FIG. 22C are connected to a portion near the second end of the conductor layer 1742.

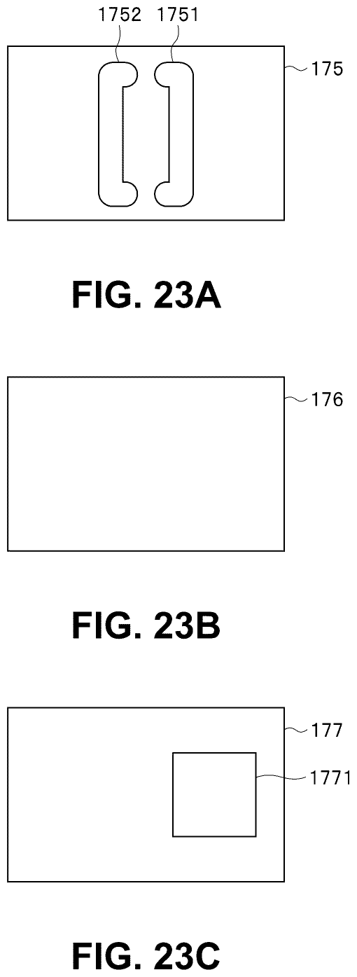

FIG. 23A shows a patterned surface of the twenty-fifth dielectric layer 175. Inductor conductor layers 1751 and 1752 are formed on the patterned surface of the dielectric layer 175. The conductor layer 1751 has a first end and a second end located at both respective ends in a longitudinal direction of the conductor layer 1751. The conductor layer 1752 has a first end and a second end located at both respective ends in a longitudinal direction of the conductor layer 1752. The through hole 174T2a is connected to a portion near the first end of the conductor layer 1751. The through hole 174T2b is connected to a portion near the second end of the conductor layer 1751. The through hole 174T3a is connected to a portion near the first end of the conductor layer 1752. The through hole 174T3b is connected to a portion near the second end of the conductor layer 1752.

FIG. 23B shows a patterned surface of the twenty-sixth dielectric layer 176. No conductor layers or through holes are formed on the patterned surface of the dielectric layer 176.

FIG. 23C shows a patterned surface of the twenty-seventh dielectric layer 177. A mark 1771 is formed on the patterned surface of the dielectric layer 177.

The stack 150 shown in FIG. 18 is formed by stacking the first to twenty-seventh dielectric layers 151 to 177 such that the patterned surface of the first dielectric layer 151 serves as the bottom surface 150A of the stack 150 and a surface opposite to the patterned surface of the twenty-seventh dielectric layer 177 serves as the top surface 150B of the stack 150.

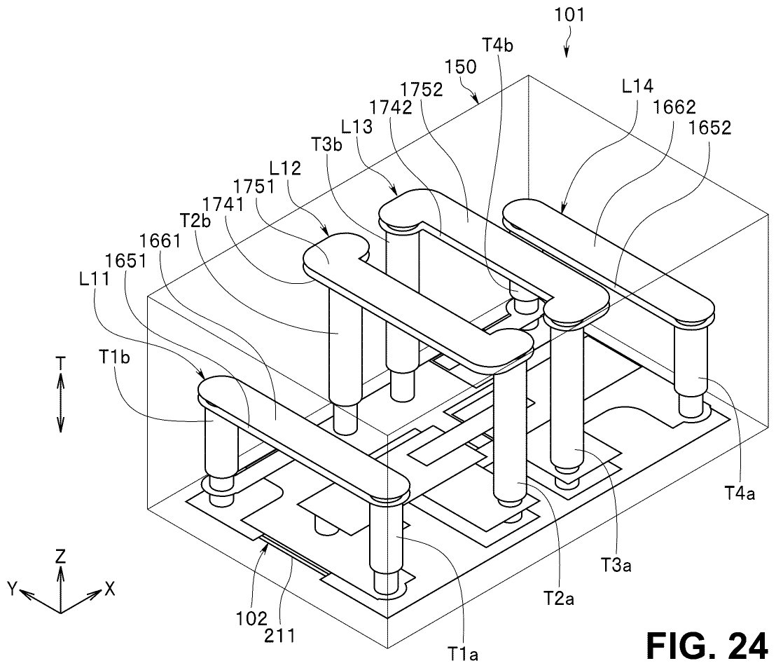

FIG. 24 shows an inside of the stack 150 formed by stacking the first to twenty-seventh dielectric layers 151 to 177. As shown in FIG. 24, the plurality of conductor layers and the plurality of through holes shown in FIG. 19A to FIG. 23A are stacked together inside the stack 150. Note that, in FIG. 24, the mark 1771 is omitted.

Correspondences between the components of the filter device 101 shown in FIG. 17 and the internal components of the stack 150 shown in FIG. 19A to FIG. 23C will be described below. The inductor L11 is composed of the inductor conductor layers 1651 and 1661, the through holes T1a and T1b, and the through holes 165T1a and 165T1b. The through hole T1a is formed by connecting the through holes 153T1a, 154T1a, 155T1a, 156T1a, 157T1a, and 158T1a in series. The through hole T1b is formed by connecting the through holes 152T1b, 153T1b, 154T1b, 155T1b, 156T1b, 157T1b, and 158T1b in series. The through holes 165T1a and the 165T1b connect the conductor layers 1651 and the 1661.

The inductor L12 is composed of the inductor conductor layers 1741 and 1751, the through holes T2a and T2b, and the through holes 174T2a and 174T2b. The through hole T2a is formed by connecting the the through holes 155T2a, 156T2a, 157T2a, 158T2a, 165T2a, 166T2a, and 167T2a in series. The through hole T2b is formed by connecting the through holes 152T2b, 153T2b, 154T2b, 155T2b, 156T2b, 157T2b, 158T2b, 165T2b, 166T2b, and 167T2b in series. The through holes 174T2a and 174T2b connect the conductor layers 1741 and 1751.

The inductor L13 is composed of the inductor conductor layers 1742 and 1752, the through holes T3a and T3b, and the through holes 174T3a and 174T3b. The through hole T3a is formed by connecting the through holes 155T3a, 156T3a, 157T3a, 158T3a, 165T3a, 166T3a, and 167T3a in series. The through hole T3b is formed by connecting the through holes 152T3b, 153T3b, 154T3b, 155T3b, 156T3b, 157T3b, 158T3b, 165T3b, 166T3b, and 167T3b in series. The through holes 174T3a and 174T3b connects the conductor layers 1742 and 1752.

The inductor L14 is composed of the inductor conductor layers 1652 and 1662, the through holes T4a and T4b, and the through holes 165T4a and 165T4b. The through hole T4a is formed by connecting the through holes 153T4a, 154T4a, 155T4a, 156T4a, 157T4a, and 158T4a in series. The through hole T4b is formed by connecting the through holes 152T4b, 153T4b, 154T4b, 155T4b, 156T4b, 157T4b, and 158T4b in series. The through holes 165T4a and 165T4b connect the conductor layers 1652 and 1662.

Note that each of the first to fourth inductors L11, L12, L13, and L14 is a rectangular or substantially rectangular winding. For the rectangular or substantially rectangular winding, the number of windings may be counted, when the winding is regarded as a rectangle, as ¼ per side of the rectangle. In the example embodiment, the number of windings of each of the first to fourth inductors L11, L12, L13, and L14 is ¾.

The capacitor C11 is composed of the conductor layers 1521, 1531, and 1541, and the dielectric layers 152 and 153 between those conductor layers. The capacitor C12 is composed of the conductor layers 1521 and 1532 and the dielectric layer 152 between those conductor layers. The capacitor C13 is composed of the conductor layers 1521 and 1533 and the dielectric layer 152 between those conductor layers. The capacitor C14 is composed of the conductor layers 1521, 1534, and 1542 and the dielectric layers 152 and 153 between those conductor layers.

The capacitor C15 is composed of the conductor layers 1551 and 1561 and the dielectric layer 155 between those conductor layers. The capacitor C16 is composed of the conductor layers 1532, 1533, 1543, 1551, and 1552 and the dielectric layers 153 and 154 between those conductor layers. The capacitor C17 is composed of the conductor layers 1552 and 1562 and the dielectric layer 155 between those conductor layers. The capacitor C18 is composed of the conductor layers 1561, 1562, and 1571 and the dielectric layer 156 between those conductor layers.

The configuration, operation, and effects of the example embodiment are otherwise the same as those of the first example embodiment.

### Example

Next, examples of the technology will be described. Initially, the temperature coefficient TCF of the resonance frequency of the dielectric layer of each of first to eighth examples will be described. Each of the dielectric layers of the first to eighth examples is a dielectric layer formed by using raw material powder including a titanate compound as a dielectric material. Each of the dielectric layers of the first to third examples is the dielectric layer formed by using the same raw material powder. Each of the dielectric layers of the fourth to eighth examples is the dielectric layer formed by using raw material powder at the same mixing rate but of a different lot. Note that each of the dielectric layers of the fourth to eighth examples is formed by using the raw material powder of a different lot from that of the raw material powder of the dielectric layer of each of the first to third examples.

In the following, the temperature coefficient TCF of the resonance frequency at −40 to 20° C. is represented by the reference sign TCF_{L}, the temperature coefficient TCF of the resonance frequency at 20 to 80° C. is represented by the reference sign TCF_{H}, and the temperature coefficient TCF of the resonance frequency at −40 to 80° C. is represented by the reference sign TCF_{L-H}.

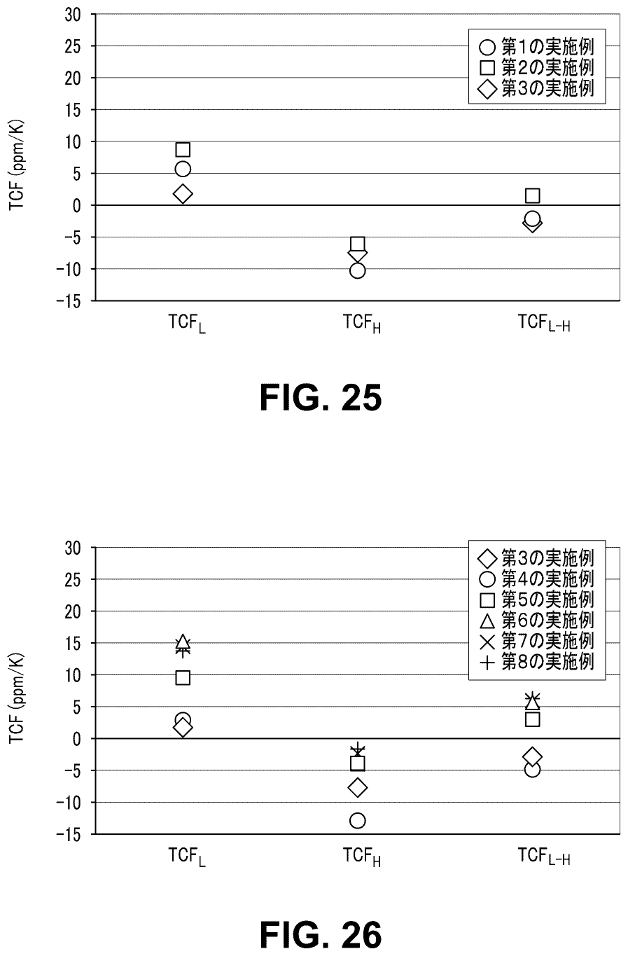

FIG. 25 is a characteristic chart showing TCF_{L}, TCF_{H}, and TCF_{L-H} of each of the first to third examples. FIG. 26 is a characteristic chart showing TCF_{L}, TCF_{H}, and TCF_{L-H} of each of the third to eighth examples. In FIG. 25 and FIG. 26, the vertical axis represents values of the temperature coefficient TCF of the resonance frequency. As shown in FIG. 25 and FIG. 26, in any of the first to eighth examples, TCF_{L} is a positive value and TCF_{H} is a negative value. In addition, as shown in FIG. 25 and FIG. 26, in any of the first to eighth examples, the absolute value of TCF_{L-H} is sufficiently small.

Next, insertion loss and pass attenuation characteristics of the filter device of the ninth example will be described. The filter device of the ninth example is a filter device corresponding to the filter device 101 according to the second example embodiment, and is designed so that the passband includes a frequency domain which is 26.5 GHz or more and 29.5 GHz or less. Each of the dielectric layers 151 to 177 is formed by using raw material powder including a titanate compound as a dielectric material.

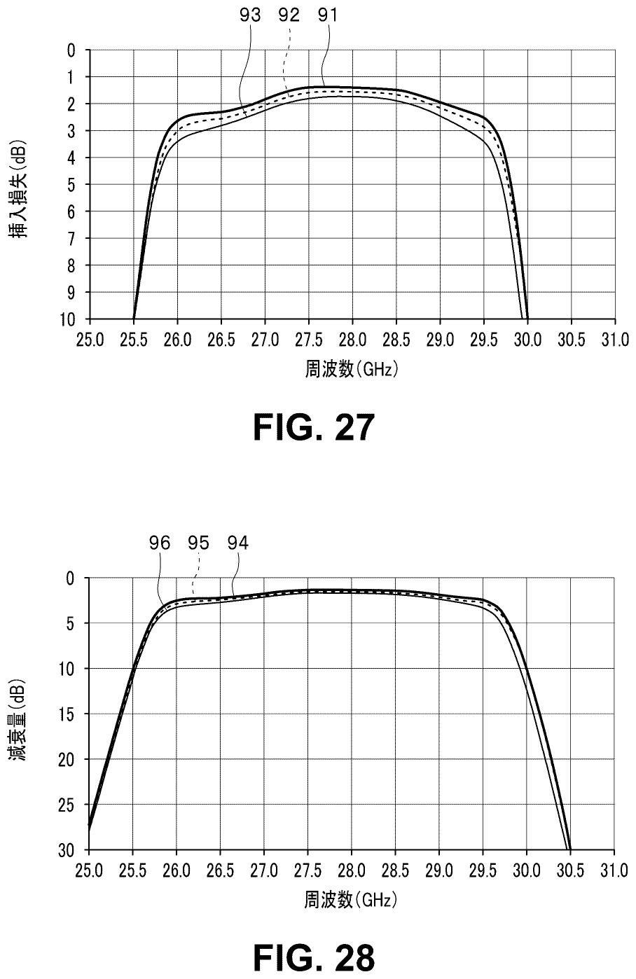

FIG. 27 is a characteristic chart showing insertion loss of the filter device of the ninth example. In FIG. 27, the horizontal axis represents the frequency, and the vertical axis represents insertion loss. In addition, in FIG. 27, the reference sign 91 indicates the insertion loss at −40° C., the reference sign 92 indicates the insertion loss at 25° C., and the reference sign 93 indicates the insertion loss at 125° C. Here, the value of the insertion loss will be described. The insertion loss at 26.5 GHz is 2.39 dB at −40° C., 2.59 dB at 25° C., and 2.89 dB at 125° C. The insertion loss at 29.5 GHz is 2.56 dB at −40° C., 2.85 dB at 25° C., and 3.39 dB at 125° C.

FIG. 28 is a characteristic chart showing pass attenuation characteristics of the filter device of the ninth example. In FIG. 28, the horizontal axis indicates the frequency, and the vertical axis indicates attenuation. In FIG. 28, the reference sign 94 indicates the pass attenuation characteristics at −40° C., the reference sign 95 indicate the pass attenuation characteristics at 25° C., and the reference sign 96 indicates the pass attenuation characteristics at 125° C. Here, the attenuation in a frequency domain where the attenuation steeply changes near the passband of the filter device of the ninth example will be described. The attenuation at 25.5 GHz is 10.84 dB at −40° C., 11.67 dB at 25° C., and 11.00 dB at 125° C. The attenuation at 30.5 GHz is 29.22 dB at −40° C., 28.71 dB at 25° C., and 31.03 dB at 125° C. From the results shown in FIG. 28, it can be seen that the attenuation hardly changes in the frequency domain below the passband in particular and in the frequency domain where the attenuation steeply changes.

Note that the technology is not limited to the above-described example embodiments, and various modifications can be made. For example, the filter device of the technology is not limited to the bandpass filter, but may be a filter device including a plurality of resonator other than the bandpass filter.

As described above, a multilayer filter device according to one embodiment of the technology includes a stack including a plurality of dielectric layers stacked together, and a resonator configured using a conductor integrated into the stack. Each of the plurality of dielectric layers is formed of a dielectric material, and has a resonance frequency that changes depending on the temperature. In the dielectric material, the resonance frequency changes linearly with respect to a change in a temperature when the temperature is within a first temperature range, and the resonance frequency changes nonlinearly with respect to the change in the temperature when the temperature is within a second temperature range.

In the multilayer filter device according to one embodiment of the technology, each of the plurality of dielectric layers may be a ceramic sintered body containing a dielectric material.

In the multilayer filter device according to one embodiment of the technology, an aspect of a change in the resonance frequency with respect to a change in the temperature when the temperature decreases from a specific temperature and an aspect of the change in the resonance frequency with respect to the change in the temperature when the temperature increases from the specific temperature may be the same. The resonance frequency may be smaller than the resonance frequency at the specific temperature in both cases where the temperature decreases from the specific temperature and where the temperature increases from the specific temperature. The specific temperature may be within the second temperature range.

In the multilayer filter device according to one embodiment of the technology, the resonance frequency may increase monotonically or decrease monotonically with respect to the change in the temperature within the first temperature range.

In the multilayer filter device according to one embodiment of the technology, the second temperature range may be a temperature range including 20° C. The first temperature range may include a first sub-range lower than the second temperature range, and a second sub-range higher than the second temperature range. The first sub-range may be narrower than the second sub-range.

In the multilayer filter device according to one embodiment of the technology, a difference between a maximum value and a minimum value of the resonance frequency within the second temperature range may be smaller than a difference between a maximum value and a minimum value of the resonance frequency within the first temperature range.

In the multilayer filter device according to one embodiment of the technology, the resonator may be an LC resonator including an inductor and a capacitor. The conductor may include an inductor conductor layer constituting the inductor and a capacitor conductor layer constituting the capacitor.

In the multilayer filter device according to one embodiment of the technology, the resonator may be a distributed constant resonator. The conductor may include a resonator conductor layer constituting the distributed constant resonator.

In the multilayer filter device according to one embodiment of the technology, in the dielectric material, the resonance frequency changes as described above. Therefore, according to one embodiment of the technology, the effect of suppressing a change in characteristics due to a temperature can be provided.

Based on the above description, obviously, various forms and modifications of the technology can be implemented. Thus, within the scope of the appended claims and equivalents thereof, the technology can be implemented in forms other than the above example embodiments.

1. A multilayer filter device comprising:
a stack including a plurality of dielectric layers stacked together; and
a resonator configured using a conductor integrated into the stack, wherein:
each of the plurality of dielectric layers is formed of a dielectric material, and has a resonance frequency that changes depending on a temperature; and
in the dielectric material, the resonance frequency changes linearly with respect to a change in the temperature when the temperature is within a first temperature range, and the resonance frequency changes nonlinearly with respect to the change in the temperature when the temperature is within a second temperature range.

2. The multilayer filter device according to claim 1, wherein each of the plurality of dielectric layers is a ceramic sintered body including the dielectric material.

3. The multilayer filter device according to claim 1, wherein an aspect of a change in the resonance frequency with respect to the change in the temperature when the temperature decreases from a specific temperature and an aspect of the change in the resonance frequency with respect to the change in the temperature when the temperature increases from the specific temperature are the same.

4. The multilayer filter device according to claim 3, wherein the resonance frequency is smaller than the resonance frequency at the specific temperature in both cases where the temperature decreases from the specific temperature and where the temperature increases from the specific temperature.

5. The multilayer filter device according to claim 4, wherein the specific temperature is within the second temperature range.

6. The multilayer filter device according to claim 1, wherein the resonance frequency increases monotonically or decreases monotonically with respect to the change in the temperature within the first temperature range.

7. The multilayer filter device according to claim 1, wherein the second temperature range is a temperature range including 20° C.

8. The multilayer filter device according to claim 7, wherein:
the first temperature range includes a first sub-range lower than the second temperature range, and a second sub-range higher than the second temperature range; and
the first sub-range is narrower than the second sub-range.

9. The multilayer filter device according to claim 1, wherein a difference between a maximum value and a minimum value of the resonance frequency within the second temperature range is smaller than a difference between a maximum value and a minimum value of the resonance frequency within the first temperature range.

10. The multilayer filter device according to claim 1, wherein:
the resonator is an LC resonator including an inductor and a capacitor; and
the conductor includes an inductor conductor layer constituting the inductor and a capacitor conductor layer constituting the capacitor.

11. The multilayer filter device according to claim 1, wherein:
the resonator is a distributed constant resonator; and
the conductor includes a resonator conductor layer constituting the distributed constant resonator.
